(19) United States
(12) Patent Application Publication
(10) Pub. No.: US 2026/0165061 A1
(43) Pub. Date: Jun. 11, 2026

(54) A SOURCE WAFER AND METHODS RELATED THERETO FOR MICRO-TRANSFER PRINTING

(71) Applicants: UNIVERSITEIT GENT, Gent (BE); IMEC VZW, Leuven (BE)

(72) Inventors: Stijn CUYVERS, Gent (BE); Gunther ROELKENS, Gent (BE); Kasper VAN GASSE, Gent (BE); Bart KUYKEN, Gent (BE)

(21) Appl. No.: 18/707,963

(22) PCT Filed: Nov. 16, 2022
(86) PCT No.: PCT/EP2022/082070

§ 371 Date: May 7, 2024

(30) Foreign Application Priority Data
Nov. 24, 2021 (EP) 21210124.0

(51) Int. Cl. H10P 54/50; H10P 72/00; H10W 80/00

(52) U.S. Cl. CPC H10P 54/50; H10P 72/0438; H10W 80/301

(57) ABSTRACT

A source wafer for micro-transfer printing, includes: a substrate; and on top of the substrate, a semiconductor film having a device coupon; and a micro-transfer printing pair formed at a periphery of the device coupon. The micro-transfer printing pair includes: a breakable tether securing the device coupon to the substrate. The breakable tether includes a breaking region; and at least one crack arrest pattern formed in the device coupon and extending at least partially through the device coupon.

### TECHNICAL FIELD

The present invention generally relates, amongst others, to a source wafer for micro-transfer printing and to a method of forming thereof. The present invention further generally relates to a semiconductor device and to a method of manufacturing thereof via micro-transfer printing.

### BACKGROUND

Passive and inorganic opto-electronic platforms manufactured from for example silicon and/or silicon nitride offer low-cost, mass-manufacturable compact opto-electronic circuits for telecommunications as well as other industrial applications using CMOS compatible fabrication techniques. However, for most applications, the material properties of these platforms by themselves do not suffice to realize the envisioned chip function. For example, owing to the indirect band gap of silicon, other materials such as III-V semiconductors are indispensable to realize integrated light sources and detectors.

Hybrid integration of opto-electronic devices, such as for example lasers, modulators, amplifiers, etc., onto passive opto-electronic platforms combines advantages conferred by both material systems.

Although bonding has been the preferred method for hybrid integration, it has several disadvantages with respect to the material use and the co-integration with other hybrid platforms. Another popular method to co-integrate different materials and/or devices with existing electronic and/or photonic platforms is the heterogeneous integration through micro-transfer printing. This pick-and-place integration process relies on the kinetically controlled adhesion of a stamp to pick devices and/or material films from a source wafer and print them on a target substrate, such as for example a target opto-electronic wafer. Micro-transfer printing allows for the integration of micrometer sized material sections or even fully pre-processed devices onto for example an opto-electronic chip with sub-micrometer precision. This ensures efficient use of the transfer printed material and enables the co-integration with other hybrid material platforms on the same chip. Examples of such fully processed devices are for example described in US2010/0306993A1. Examples of micro-transfer printing techniques are for example described in US2021/0135649A1.

Micro-transfer printing can be used in a broad range of manufacturing processes and applications. For example, with ultra-low losses, the silicon nitride platform is particularly promising in the pursuit of for example lasers with higher powers and improved noise performance. However, due to the low refractive index of silicon nitride compared to that of III-V semiconductors, an intermittent coupling layer, such as for example a silicon coupling layer, is indispensable to ensure a high coupling efficiency between the silicon nitride waveguide and the III-V waveguide. A two-step micro-transfer printing process to integrate a thin intermittent silicon layer and a III-V amplifier is therefore an attractive procedure to manufacture for example active photonic devices on generic commercially available silicon nitride photonic platforms. Other devices such as for example electro-optic modulators with ultra-high modulation speeds can be realized on the same chip by micro-transfer printing a thin film of lithium niobate on silicon nitride. The heterogeneous integration of these thin material films/devices therefore enables the development of for example improved photonic transceivers both for long-haul as well as for short-reach optical links. Other applications such as on-chip spectroscopic sensing and ultra-fast lidar can benefit greatly from this technical advancement, as the heterogeneous integration of silicon films serves as a convenient tool to fabricate for example on-chip optical frequency combs on silicon nitride. It is further highly desirable to for example extend the material portfolio of integrated photonics to include for example nonlinear materials such as gallium phosphide. The heterogeneous integration of highly nonlinear materials could allow for on-chip optical frequency combs with shorter optical pulses and broader comb spectra, features deemed essential to reach beyond state-of-the-art performance. Moreover, highly nonlinear optical materials are expected to play a salient role in various other applications, including for example frequency converters for telecommunication and quantum photonics.

It should be noted that transfer printing has also demonstrated extraordinary capabilities to assemble a wide range of organic materials, such as for example organic semiconductors and/or cell-sheet-integrated devices for flexible bioelectronics, onto various target substrates for flexible and stretchable organic electronics. Transfer printing can also be used to assemble for example carbon materials such as graphene onto various target substrates.

One technical obstacle preventing high yield and reliable micro-transfer printing of for example thin material films and/or devices is the occurrence of cracks in the material during the pick-up of the films and/or devices. These cracks typically originate from the supporting structures formed in the source wafer which are often denoted as tethers, and which suspend the material film on the source wafer. During micro-transfer printing, more particularly during the pick-up and/or during the printing, stress induced at these tethers can result in crack formation and crack propagation through the entire structure, leading to severe and intolerable damage of the co-integrated material coupon onto which the devices and/or the material films are formed.

Approaches for the heterogeneous integration of for example semiconductor materials on target substrates through micro-transfer printing mostly relies on an encapsulation with for example photoresist and/or silicon nitride that most preferable completely covers the film and/or the device. In this case, the supporting encapsulation tethers are defined in a material distinct from the coupon itself, preventing cracking of the film during printing.

However, coupon encapsulation requires additional fabrication steps, increasing the overall processing time and cost. Moreover, most photoresists and silicon nitride encapsulations are not resilient to some of the widely used release etchants required to suspend the coupons on the source wafer. For example, silicon nitride and most photoresists are attacked by hydrofluoric acid, a chemical used to enable micro-transfer printing of lithium niobate and silicon films.

### SUMMARY

It is thus an object of embodiments of the present invention to propose a source wafer for micro-transfer printing and a method of forming thereof which do not show the inherent shortcomings of the prior art. More specifically, it is an object of embodiments of the present invention to propose a source wafer for micro-transfer printing with which excellent reliability and high printing yield are achieved and which eliminates additional processing steps, thereby reducing the overall processing time and cost. It is a further object of embodiments of the present invention to propose a semiconductor device heterogeneously integrated onto a target substrate via micro-transfer printing using a source wafer and a related manufacturing method.

The scope of protection sought for various embodiments of the invention is set out by the independent claims.

The embodiments and features described in this specification that do not fall within the scope of the independent claims, if any, are to be interpreted as examples useful for understanding various embodiments of the invention.

There is a need for a method of manufacturing a source wafer and for the obtained source wafer which provides excellent reliability and enables a high micro-transfer printing yield, thereby improving the volume yield to render the process commercially viable. More particularly, there is a need for mitigating crack propagation originating from stress induced at the supporting tethers of a suspended material membrane during micro-transfer printing.

This object is achieved, according to a first example aspect of the present disclosure, by a source wafer for micro-transfer printing, wherein the source wafer comprises:
a substrate; and
on top of the substrate, a semiconductor film comprising:
   a device coupon comprising a periphery corresponding to a boundary of the device coupon, wherein the periphery comprises a coupling portion; and
   a micro-transfer printing pair formed at the periphery of the device coupon, wherein the micro-transfer printing pair comprises:
      a breakable tether securing the device coupon to the substrate, wherein the breakable tether comprises a breaking region narrower than adjacent regions of the breakable tether along a parallel direction parallel to the periphery of the device coupon, the breaking region thereby having a lower shear strength than the adjacent regions; and wherein the breakable tether comprises a coupling segment coupling the coupling portion to the breaking region; and
      at least one crack arrest pattern formed in the device coupon and extending at least partially through the device coupon wherein the coupling portion extends between the crack arrest pattern and the breaking region.

A source wafer according to the present disclosure provides excellent reliability and enables a high micro-transfer printing yield, thereby improving the volume yield to render the micro-transfer printing process commercially viable. Indeed, the crack arrest pattern, formed in the device coupon and extending at least partially through the device coupon, mitigates the occurrence of cracks originating from stress induced at the breakable tethers and propagating in and/or along the device coupon. The crack arrest pattern prevents the propagation of cracks originating at the breakable tethers for example when the device coupon is picked up from the source wafer and the breaking region of the breakable tether breaks to release the device coupon from the semiconductor film. In other words, even if one or more cracks are induced at one or more breakable tethers when the breaking region breaks, the cracks will be terminated by one or more crack arrest patterns according to the present disclosure and will not propagate in and/or along the device coupon. When a crack is generated, the crack tends to propagate from the breakable tether in a traverse direction and/or a parallel direction to the periphery of the device coupon. With the source wafer according to the present disclosure, the crack arrest pattern is provided to prevent the crack from propagating into the device coupon.

The source wafer according to the present disclosure can be seen as a refinement of the existing micro-transfer printing technology for the heterogeneous integration of for example semiconductor films and/or devices on target substrates such as for example photonic integrated circuits. Unlike photoresist and/or silicon nitride encapsulation, the present disclosure eliminates additional processing steps, e.g., the deposition and the patterning of the encapsulation using lithography and dry-or wet-etching as well as the selective encapsulation removal after micro-transfer printing. The present disclosure thereby reduces the overall processing time, complexity, and cost. Additionally, the absence of the encapsulation of the device coupon encapsulation avoids potential compatibility issues with wet and/or vapor chemicals for the release etch of the device coupon.

The main application of the source wafer according to the present disclosure is the reliable high-yield heterogeneous integration of material films such as-but not limited to-silicon, germanium, lithium niobate, gallium phosphide and/or of other devices based on these thin films on a target substrate corresponding to for example one or more of the following: generic integrated photonic platforms, generic integrated electronic platforms, diamond, any flexible substrate such as for example any polymer, silicon, dielectrics, glass, etc. For example, in optical communication, the use of a source wafer according to the present disclosure will aid the fabrication of high-performance integrated light sources and modulators on silicon nitride.

In the context of the present disclosure related to the semiconductor technology, a crack is to be understood as a cleavage or fracture that extends to the surface of the device coupon and which may or may not pass through at least partially the thickness of the device coupon. In other words, a crack is to be understood as a fissure originating for example from the periphery of the device coupon and propagating to the surface of the device coupon and/or through at least partially the thickness of the device coupon.

In the context of the present disclosure, the crack arrest pattern formed in the device coupon extends at least partially through the thickness of the device coupon in the semiconductor film. Preferably, the crack arrest pattern extends through at least 50% of the total thickness of the device coupon in the semiconductor film. In other words, the crack arrest pattern extends through at least 50% of the total thickness of the device coupon along a direction which is traverse to the plane comprising the interface between the semiconductor film and the substrate. This way, the crack arrest pattern prevents the propagation of cracks in and/or along the device coupon, such as for example along the traverse direction defined below and/or along the parallel direction defined below and/or through the thickness of the device coupon. For example, the crack arrest pattern prevents the propagation of cracks at the surface of the device coupon facing away from the interface between the semiconductor film and the substrate. The crack arrest pattern according to the present disclosure can have any shape in projection on a plane comprising the semiconductor film and parallel to the interface between the semiconductor film and the substrate, for example a square, a rectangle, a polygon, a circle, an ellipse, etc. For example, the crack arrest pattern has a surface of a few μm² or tens or hundreds of μm². Alternatively, the crack arrest pattern has a surface of a few nm² or tens or hundreds of nm². A crack arrest pattern in the context of the present invention can also be referred to as a crack terminating pattern or crack arrest structure or crack stop or crack arrester or crack-propagating preventing structure or a crack integrity controlling pattern. A crack arrest pattern in the context of the present disclosure at least partially spans in a direction parallel to the coupling portion of the periphery of the device coupon.

In the context of the present disclosure, the semiconductor film comprises a micro-transfer printing pair which comprises a breakable tether and at least one crack arrest pattern. In other words, in the source wafer according to the present disclosure, to each breakable tether corresponds at least one crack arrest pattern. A crack arrest pattern is placed for every breakable tether as cracks can originate from any breakable tether with the same likelihood. Alternatively, a crack arrest pattern is placed for multiple breakable tethers simultaneously so that every breakable tether is safeguarded by at least one crack arrest pattern as one or more cracks can originate from any breakable tether with the same likelihood.

In the context of the present disclosure, a semiconductor film and/or a device coupon comprises one or more constituent layers. The device coupon is embedded in a portion of the semiconductor film acting as a support layer for the device coupon. The device coupon according to the present disclosure can have any shape in projection on a plane comprising the semiconductor film and parallel to the interface between the semiconductor film and the substrate, for example a square, a rectangle, a polygon, a circle, an ellipse, etc. A thickness of the semiconductor film is for example a few tens or a few hundreds of nanometers. Alternatively, a thickness of the semiconductor film is for example a few tens or a few hundreds of micrometers.

In the context of the present disclosure, the semiconductor film may comprise one or more device coupons. The semiconductor film may comprise one or more micro-transfer printing pairs formed at a periphery of each device coupon. Alternatively, the semiconductor film may comprise one or more micro-transfer printing pairs formed at a periphery of one or more device coupons.

In the context of the present disclosure, a periphery of the device coupon corresponds to the edge of the device coupon. In other words, the periphery of the device corresponds to the outermost boundary of the device coupon. The periphery of the device coupon is to be understood in the context of the present disclosure as the surface which corresponds to the sidewall boundary of the device coupon surrounding the device coupon. The periphery of the source wafer according to the present disclosure can have any shape, for example a square, a rectangle, a polygon, a disk, an ellipse, etc. The periphery may be a lateral one, i.e. one across the plane of the substrate.

In the context of the present disclosure, a breaking region of a breakable tether corresponds to a region of the breakable tether which has been deliberately engineered to be weak and so preferentially break when the device coupon is lifted away from the substrate. In other words, the breaking regions of the breakable tethers have a lower shear strength than adjacent regions of the breakable tether and the breaking regions are engineered to fracture or break or cleave in a controller manner. The breakable tether according to the present disclosure is formed in the semiconductor film and secures the device coupon to the substrate, wherein the breakable tether comprises a breaking region. In other words, the breakable tether and its breaking region comprise the same constituents than the device coupon. Alternatively, the device coupon and the breakable tether do not comprise the same constituents. Alternatively, the device coupon and the breaking region do not comprise the same constituents. For example, the breaking regions of the breakable tethers are only a few μm wide, while adjacent regions of the breakable tethers are tens of μm wide.

In the context of the present disclosure, the device coupon may be secured to the substrate only by the breaking regions of the breakable tethers.

In the context of the present disclosure, the substrate comprises one or more of the following: silicon, silicon-on-insulator, silicon carbide, sapphire, silicon nitride, germanium, germanium-on-insulator, III-V such as for example GaN and/or AIN, etc. This way, the manufacturing of the source wafer of the present invention is compatible with existing manufacturing techniques developed for example for the complementary metal-oxide-semiconductor technology and processes. In other words, the manufacturing of the source wafer according to the present disclosure is CMOS-compatible as present features and present process steps can be integrated therein without much additional effort. This reduces the complexity and the costs associated with manufacturing such a source wafer.

In the context of the present disclosure, a device coupon can therefore comprise one or more of the following: silicon, silicon nitride, silicon oxide, lithium niobate, one or more III-V semiconductor material such as for example such as InP, GaN, GaP, GaAs, and/or ternaries such as InGaN, InGaAs, and/or quaternaries such as InGaAsN, quantum-wells, one or more II-VI semiconductor material, germanium, other devices based on these thin films, any polymer, any dielectric. The device coupon may further comprise one or more protective outer layers. The protective outer layers may comprise one or more of the following: silicon dioxide, silicon nitride, a combination thereof, photoresist.

According to example embodiments, the crack arrest pattern extends through the device coupon.

The crack arrest pattern extends through the total thickness of the device coupon in the semiconductor film. The crack arrest pattern is etched through the thickness of the device coupon in the semiconductor film. In other words, the crack arrest pattern is hollow along a direction which is traverse to the plane comprising the interface between the semiconductor film and the substrate. This way, the crack arrest pattern mitigates the occurrence of cracks originating from stress induced at the breakable tethers and which propagate in and/or along the device coupon, such as for example along the traverse direction defined below and/or along the parallel direction defined below and/or through the thickness of the device coupon. For example, the crack arrest pattern prevents the propagation of cracks at the surface of the device coupon facing away from the interface between the semiconductor film and the substrate. For example, the crack arrest pattern prevents the propagation of cracks at the interface between the semiconductor film and the substrate.

The crack arrest pattern preferably extends entirely through the thickness of the device coupon. In other words, the crack arrest pattern is hollow and extends between a projection of the shape of the crack arrest pattern in a plane comprising the surface of the device coupon facing away from the interface between the semiconductor film and the substrate and a projection of the shape of the crack arrest pattern in a plane comprising the interface between the semiconductor film and the substrate. This way, the crack arrest pattern extends completely through the thickness of the device coupon. Alternatively, only one or more regions of the crack arrest pattern extend entirely through the thickness of the device coupon, while one or more other regions of the crack arrest pattern extend partially through the thickness of the device coupon, for example through at least 50% of the thickness of the device coupon. In other words, in this alternative embodiment, the crack arrest pattern is partially hollow and extends between a projection of the shape of the crack arrest pattern in a plane comprising the surface of the device coupon facing away from the interface between the semiconductor film and the substrate and a projection of the shape of the crack arrest pattern in a plane comprising the interface between the semiconductor film and the substrate. This way, the crack arrest pattern extends partially through the thickness of the device coupon.

According to example embodiments, the periphery of the device coupon comprises a coupling portion and the breakable tether comprises a coupling segment extending along the coupling portion of the periphery; and the coupling segment couples the coupling portion to the breaking region of the breakable tether.

The coupling segment of the breakable tether and the coupling portion of the device coupon are coupled to each other continuously along the periphery of the device coupon. This way, the coupling segment securely couples the coupling portion to the breaking region of the breakable tether. Alternatively, the coupling segment of the breakable tether and the coupling portion of the device coupon are not continuously but are intermittently coupled to each other along the periphery of the device coupon. This way, fracture of the breaking region of the breakable tether is made easier when the device coupon is lifted off or picked up from the source wafer for micro-transfer printing.

According to example embodiments, the breakable tether extends along a traverse direction traverse to the periphery of the device coupon; and the crack arrest pattern is formed in the device coupon at a distance from the coupling portion equal to or larger than a length of the coupling portion along the periphery.

The breakable tether extends along a traverse direction traverse to the coupling section of the periphery of the device coupon. Additionally, a minimum distance between the crack arrest pattern and the coupling portion of the periphery coupled to the coupling segment of the breakable tether is equal to a length of the coupling portion along the periphery of the device coupon. This way, the device coupon comprises a strip formed between the coupling portion and the crack arrest pattern. The crack arrest pattern is formed far enough from the coupling portion to ensure the strip of device coupon formed between the coupling portion and the crack arrest pattern is mechanically strong enough not to break during the fracture of the breaking region of the breakable tether when the device coupon is lifted off or picked up from the source wafer for micro-transfer printing. Preferably, the crack arrest pattern is formed such that the distance from any point of the crack arrest pattern to the coupling portion, in a plane comprising the surface of the device coupon facing away from the interface between the semiconductor film and the substrate, is equal to or larger than a length of the coupling portion along the periphery. This way, the distance between the breakable tether and the crack arrest pattern is small enough to minimize the area of the device coupon required to form the crack arrest pattern while ensuring sufficient mechanical strength to avoid premature breaking during micro-transfer printing. In other words, the crack arrest patter according to the present disclosure is formed in the device coupon such that no line perpendicular to the coupling portion of the periphery of the device coupon can be drawn between any point of the breaking region and the device coupon without intersecting a crack arrest pattern.

Additionally, the width of the crack arrest pattern along the traverse direction is sufficiently small to minimize the area of the device coupon required to form the crack arrest pattern while being sufficiently large to allow reliable patterning and etching with existing manufacturing tools of the crack arrest pattern.

According to example embodiments, a length of the crack arrest pattern along a parallel direction parallel to the periphery of the device coupon is equal to or larger than half the length of the coupling portion along the periphery.

This way, the length of the crack arrest pattern exceeds the span of the breakable tether. This ensures that a crack originating from the breakable tether reaches the crack arrest pattern and avoids further crack propagation along the device coupon.

According to example embodiments, the breaking region is thinner than adjacent regions of the breakable tether along a third direction traverse to the traverse direction and to the parallel direction and/or wherein the breaking region is narrower than adjacent regions of the breakable tether along the parallel direction.

This way, the breaking region of the breakable tether is more likely to fracture when the device coupon is picked up from the source wafer, thereby releasing the device coupon from the source wafer. By thinner, it may be meant that a dimension of the breaking region as measured in a direction out of the plane of the substrate is smaller than equivalent dimensions of adjacent regions of the breakable tether. By narrower, it may be meant that a dimension of the breaking region as measured across the plane of the substrate is smaller than equivalent dimensions of adjacent regions of the breakable tether.

According to example embodiments, a midline of the breakable tether along the parallel direction coincides with a midline of the crack arrest pattern along the parallel direction.

This way, the position of the crack arrest pattern with respect to the breaking region of the breakable tether is optimized to maximize a number of cracks generated at the breaking region being terminated by the crack arrest pattern.

According to example embodiments, a width of the crack arrest pattern along the traverse direction fans out with an increasing distance from the midline of the crack arrest pattern.

The slightly larger width along the traverse direction of the crack arrest pattern provides a way to surround the breakable tether. This way, the crack arrest pattern mitigates the impact of one or more cracks which propagate close to the periphery of the device coupon. For example, such crack arrest pattern mitigates cracks which propagate in the device coupon under an angle comprised for example between 0.3° and 20° from the periphery of the device coupon, preferably for example between 0.3° and 10° from the periphery of the device coupon.

According to example embodiments, the source wafer further comprises a cavity extending at least partially between the device coupon and the substrate and at least partially around the device coupon; the cavity is bridged by the breakable tether, thereby securing the device coupon to the substrate.

This way, the device coupon is only secured to the semiconductor film and consequently to the substrate via the breakable tether. The device coupon can easily be released from the source wafer upon fracture of the breakable tether.

According to example embodiments, the micro-transfer printing pair comprises a plurality of crack arrest patterns.

This way, the device coupon is only secured to the semiconductor film and consequently to the substrate via the breakable tethers. The device coupon can easily be released from the source wafer upon fracture of the breakable tethers.

The crack arrest patterns are distributed along the traverse direction and/or along the parallel direction. A micro-transfer printing pair can comprise two or more crack arrest patterns corresponding to a single breakable tether. For example, to one breakable tether corresponds tens of crack arrest patterns distributed and formed in the device coupon along the traverse direction and/or the parallel direction.

According to example embodiments, the crack arrest patterns are formed in the device coupon between two lines originating from extremities of the coupling segment and each extending away from the coupling portion under an angle comprised between 0.3° and 89° from the periphery of the device coupon.

This way, the crack arrest pattern mitigates the impact of one or more cracks which propagate close to the periphery of the device coupon. For example, such crack arrest pattern mitigates cracks which propagate in the device coupon under an angle larger than 0.3° from the periphery of the device coupon. Additionally, the crack arrest pattern also mitigates cracks which propagate in the device coupon under an angle smaller than 89° from the periphery of the device coupon.

When the micro-transfer printing pair comprises a plurality of crack arrest patterns, the plurality of crack arrest patterns is formed in the device coupon between two lines originating from extremities of the coupling segment and each extending away from the coupling portion under an angle comprised between 0.3° and 89° from the periphery of the device coupon. In other words, the plurality of crack arrest pattern is distributed along the traverse direction and/or the parallel direction and between two lines originating from extremities of the coupling segment and each extending away from the coupling portion under an angle comprised between 0.3° and 89° from the periphery of the device coupon.

According to example embodiments, the semiconductor film comprises a plurality of micro-transfer printing pairs formed along the periphery of the device coupon.

Each micro-transfer printing pairs comprises a breakable tether securing the device coupon to the substrate, wherein the breakable tether comprises a breaking region; and at least one crack arrest pattern formed in the device coupon and extending at least partially through the device coupon. The plurality of micro-transfer printing pairs is distributed along the periphery of the device coupon. For example, the micro-transfer printing pairs may be periodically distributed along the periphery of the device coupon. The micro-transfer printing pairs may be disposed at equidistant points around the periphery of the device coupon. Alternatively, one or more portions of the periphery of the device coupon comprise more micro-transfer printing pairs than other portions of the periphery of the device coupon. There can be more micro-transfer printing pairs formed on one side of the device coupon than on other sides of the device coupon.

According to example embodiments, an array of device coupons is produced on the source wafer and one or more of the device coupons of the array are simultaneously transferred to the target substrate.

According to a second example aspect of the present disclosure, there is provided a method for forming a source wafer for micro-transfer printing, the method comprising the steps of:
providing a substrate;
on top of the substrate, providing a sacrificial layer;
on top of the sacrificial layer, providing a semiconductor film;
defining a designed device coupon on the semiconductor film;
defining a designed micro-transfer printing pair at a periphery of the designed device coupon, wherein the designed micro-transfer printing pair comprises:
   a designed breakable tether comprising a designed breaking region; and
   a designed crack arrest pattern defined in the designed device coupon;
etching:
   the sacrificial layer away at least partially between the designed device coupon and the substrate, thereby forming a device coupon suspended above the substrate and a cavity extending at least partially between the device coupon and the substrate and at least partially around the device coupon; the device coupon comprising a periphery corresponding to a boundary of the device coupon, wherein the periphery comprises a coupling portion;
   the sacrificial layer away at least partially between the designed breakable tether and the substrate, thereby forming a breakable tether comprising a breakable region narrower than adjacent regions of the breakable tether along a parallel direction parallel to the periphery of the device coupon, the breaking region thereby having a lower shear strength than the adjacent regions; wherein the breakable tether comprises a coupling segment coupling the coupling portion to the braking region along the periphery; and wherein the breakable tether secures the device coupon to the substrate and bridges the cavity by the breakable tether; and
   the designed crack arrest pattern at least partially through the device coupon, thereby forming a crack arrest pattern with the coupling portion extending between the crack arrest pattern and the breaking region.

The crack arrest pattern according to the present disclosure may be fabricated using lithographic patterning and dry- and/or wet-etching techniques, for example simultaneously with the patterning of the device coupon itself, thereby avoiding the need for additional processing steps.

The method of forming a source wafer according to the present disclosure provides excellent reliability and enables a high micro-transfer printing yield, thereby improving the volume yield to render the micro-transfer printing process commercially viable. Indeed, the crack arrest pattern, formed in the device coupon and extending at least partially through the device coupon, mitigates the occurrence of cracks originating from stress induced at the breakable tethers and propagating in and/or along the device coupon. The crack arrest pattern prevents the propagation of cracks originating at the breakable tethers for example when the device coupon is picked up from the source wafer and the breaking region of the breakable tether breaks to release the device coupon from the semiconductor film. In other words, even if one or more cracks are induced at one or more breakable tethers when the breaking region breaks, the cracks will be terminated by one or more crack arrest patterns according to the present disclosure and will not propagate in and/or along the device coupon. When a crack is generated, the crack tends to propagate from the breakable tether in a traverse direction and/or a parallel direction to the periphery of the device coupon. With the source wafer according to the present disclosure, the crack arrest pattern is provided to prevent the crack from propagating into the device coupon.

The method of forming a source wafer according to the present disclosure can be seen as a refinement of the existing micro-transfer printing technology for the heterogeneous integration of for example semiconductor films and/or devices on target substrates such as for example photonic integrated circuits. Unlike photoresist and/or silicon nitride encapsulation, the method of forming a source wafer according to the present disclosure eliminates additional processing steps, e.g., the deposition and the patterning of the encapsulation using lithography and dry-or wet-etching as well as the selective encapsulation removal after micro-transfer printing. The method of forming a source wafer according to the present disclosure thereby reduces the overall processing time, complexity, and cost. Additionally, the absence of the encapsulation of the device coupon encapsulation avoids potential compatibility issues with wet and/or vapor chemicals for the release etch of the device coupon.

The main application of the method of forming a source wafer according to the present disclosure is the reliable high-yield heterogeneous integration of material films such as—but not limited to—silicon, lithium niobate, gallium phosphide and/or of other devices based on these thin films on a target substrate corresponding to for example one or more of the following: generic integrated photonic platforms, generic integrated electronic platforms, diamond, any flexible substrate such as for example any polymer, silicon, dielectrics, glass, etc. For example, in optical communication, the use of a source wafer according to the present disclosure will aid the fabrication of high-performance integrated light sources and modulators on silicon nitride.

According to a third example aspect of the present disclosure, there is provided a method of manufacturing a semiconductor device heterogeneously integrated onto a target substrate via micro-transfer printing using the source wafer of a first example aspect of the present disclosure, wherein the method comprises the steps of:
adhering the device coupon onto a stamp;
lifting the device coupon adhered onto the stamp away from the substrate, thereby breaking one or more of the breakable tethers at the breakable regions; and
pressing the device coupon adhered onto the stamp onto the target substrate, thereby printing the device coupon onto the target substrate.

In the context of the present disclosure, a stamp is for example an elastomeric stamp which demonstrates enough softness to mediate physical mass transfer of the device coupon between the source wafer to a target substrate. Alternatively, a stamp is for example a probe microscope such as a scanning probe microscope or an atomic force microscope which demonstrates enough softness to mediate physical mass transfer of the device coupon between the source wafer to a target substrate The method according to a third example aspect of the present disclosure typically includes a retrieval or pick-up of the device coupon from the source wafer and the printing or delivery of the device coupon onto the target substrate. The device coupon is prepared to be released from the source wafer, for example by wet etching of the sacrificial layer formed in between the device coupon and the substrate and is suspended above the substrate by being secured by the breakable tethers. Conformal contact between the stamp and the device coupon is ensured by applying an appropriate load onto the stamp. Only one device coupon can be picked up from the source wafer. This selective retrieval allows precise manipulation of the device coupon. Alternatively, several device coupons are simultaneously picked up from the source wafer with a single stamp. This non-selective retrieval allows high throughput for the micro-transfer printing process. The device coupons are then brought into contact onto the target substrate. The removal of the stamp from the device coupon completes the micro-transfer printing process.

According to a fourth example aspect of the present disclosure, there is provided a semiconductor device manufactured using the method according to a third example aspect of the present disclosure.

In the context of the present disclosure, a semiconductor device can therefore comprise one or more of the following: silicon, silicon nitride, silicon oxide, lithium niobate, one or more III-V semiconductor material such as for example InP, GaN, GaP, one or more II-VI semiconductor material, other devices based on these thin films, any polymer, any dielectric.

In the context of the present disclosure, a semiconductor device can be an electronic device and/or an optical device. For example, a semiconductor device is a photodetector, a laser, an electro-optic modulator, a mirror, a pump, an amplifier, a grating, a waveguide, etc.

The current disclosure in addition also relates to a computer program comprising software code adapted to perform the method according to the present disclosure. The current disclosure further relates to a computer readable storage medium comprising the computer program according to the present disclosure. The current disclosure further relates to a computer readable storage medium comprising computer-executable instructions which, when executed by a computing system, perform the method according to the present disclosure.

### BRIEF DESCRIPTION OF THE DRAWINGS

Some example embodiments will now be described with reference to the accompanying drawings.

FIG. 1 depicts a top view of an example embodiment of a source wafer according to the present disclosure.

FIG. 2 depicts a zoom in a top view of an example embodiment of a micro-transfer printing pair on a source wafer according to the present disclosure.

FIG. 3 depicts a side view of an example embodiment of a source wafer according to the present disclosure, wherein a designed crack arrest pattern extends partially through a designed device coupon.

FIG. 4 depicts a side view of an example embodiment of a source wafer according to the present disclosure, wherein a crack arrest pattern extends partially through a device coupon.

FIG. 5 depicts a side view of an example embodiment of a source wafer according to the present disclosure, wherein a designed crack arrest pattern extends through a designed device coupon.

FIG. 6 depicts a side view of an example embodiment of a source wafer according to the present disclosure, wherein a crack arrest pattern extends through a device coupon.

FIG. 7 depicts a top view of an example embodiment of a source wafer according to the present disclosure comprising a plurality of micro-transfer printing pairs.

FIG. 8 depicts a top view of an example embodiment of a source wafer according to the present disclosure, wherein a micro-transfer printing pair comprises a plurality of crack arrest patterns.

FIG. 9 depicts a top view of an example embodiment of a source wafer according to the present disclosure, wherein a micro-transfer printing pair is formed between two lines.

FIG. 10 depicts an example embodiment of a method of manufacturing a semiconductor device with micro-transfer printing and according to the present disclosure.

FIG. 11 depicts a zoom in a top view of an example embodiment of a micro-transfer printing pair on a source wafer according to the present disclosure.

### DETAILED DESCRIPTION OF EMBODIMENT(S)

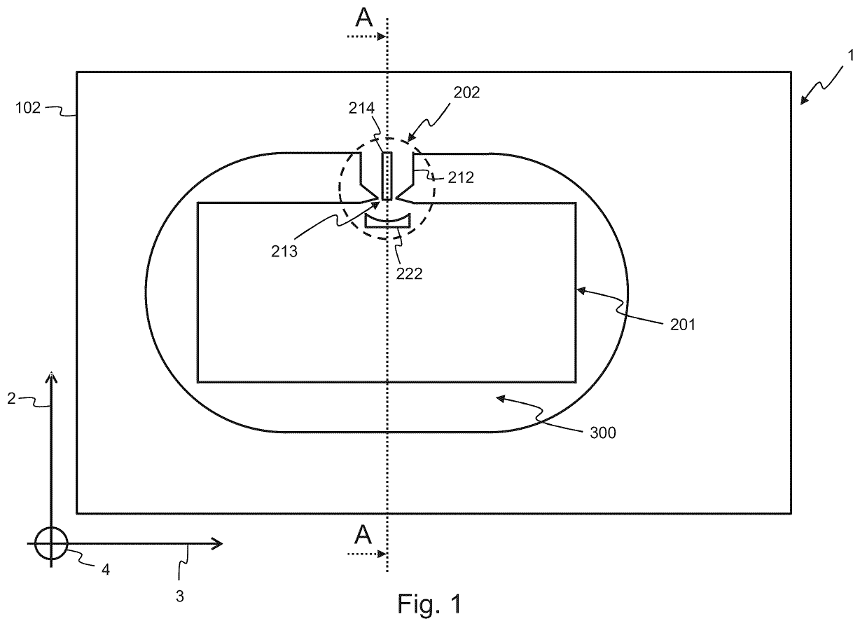

FIG. 1 schematically depicts a top view of an example embodiment of a source wafer 1 for micro-transfer printing according to the present disclosure. The source wafer 1 comprises a substrate and a semiconductor film 102 on top of the substrate. The semiconductor film 102 comprises a device coupon 201 and a micro-transfer printing pair 202. The micro-transfer printing pair 202 is formed at the periphery of the device coupon 201. The micro-transfer printing pair 202 comprises a breakable tether 212 securing the device coupon 201 to the substrate. The breakable tether 212 comprises a breaking region 213. The micro-transfer printing pair 202 further comprises at least one crack arrest pattern 222 formed in the device coupon 201 and extending at least partially through the device coupon along the third direction 4 traverse to the traverse direction 2 and to the parallel direction 3. For example, the crack arrest pattern 222 is 16 μm long along the parallel direction 3 and is 2 μm thick along the traverse direction 2 close the midline of the crack arrest pattern 222 along the traverse direction 2 and 3 μm thick further away from the midline along the parallel direction 3, and the crack arrest pattern 222 is formed at 4 μm from the periphery of the device coupon 201. Typically, the crack arrest pattern is formed at a distance comprised between 500 nm and 50 μm from the periphery of the device coupon where the device coupon is suspended by the breakable tether and the crack arrest pattern is hundreds of μm long along the parallel direction 3. Typically, a breaking region is 1 μm thick along the parallel direction 3. Optionally, the breakable tether 212 comprises an opening 214 or trench 214 extending along the traverse direction 2. The breaking region 213 of the breakable tether 212 is thinner than adjacent regions of the breakable tether 212 along the third direction 4 and/or the breaking region 213 of the breakable tether 212 is narrower than adjacent regions of the breakable tether 212 along the parallel direction 3. A midline along the parallel direction 3 of the breakable tether 212, wherein the midline extends along the traverse direction 2 as depicted in the line A-A on FIG. 1, coincides with a midline along the parallel direction 3 of the crack arrest pattern 222. A width of the crack arrest pattern 222 along the traverse direction 2 fans out with an increasing distance from the midline of the crack arrest pattern 222. The source wafer 1 further comprises a cavity 300 extending at least partially between the device coupon 201 and the substrate and at least partially around the device coupon 201. For example, the cavity 300 is an air gap. The cavity 300 is bridged by the breakable tether 212, thereby securing the device coupon 201 to the substrate.

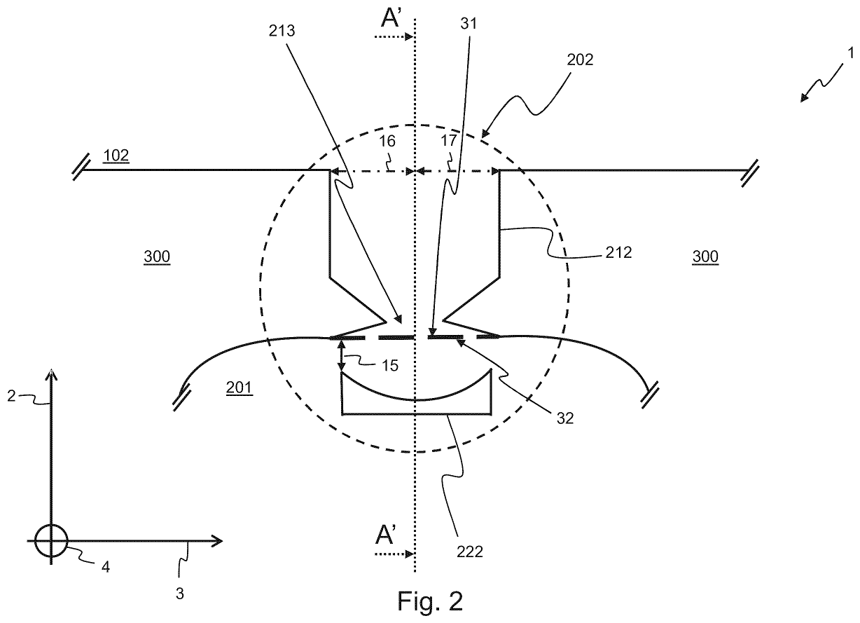

FIG. 2 schematically depicts a top view of a zoom on an example embodiment of a micro-transfer printing pair 202 of a source wafer 1 for micro-transfer printing according to the present disclosure. Components having identical reference numbers to components in FIG. 1 perform the same function. The source wafer 1 comprises a substrate and a semiconductor film 102 on top of the substrate. The semiconductor film 102 comprises a device coupon 201 and a micro-transfer printing pair 202. The micro-transfer printing pair 202 is formed at the periphery of the device coupon 201. The micro-transfer printing pair 202 comprises a breakable tether 212 securing the device coupon 201 to the substrate. The breakable tether 212 comprises a breaking region 213. The micro-transfer printing pair 202 further comprises at least one crack arrest pattern 222 formed in the device coupon 201 and extending at least partially through the device coupon along the third direction 4 traverse to the traverse direction 2 and to the parallel direction 3. Optionally, the breakable tether 212 comprises an opening or trench extending along the traverse direction 2. The breaking region 213 of the breakable tether 212 is thinner than adjacent regions of the breakable tether 212 along the third direction 4 and/or the breaking region 213 of the breakable tether 212 is narrower than adjacent regions of the breakable tether 212 along the parallel direction 3. The periphery of the device coupon 201 comprises a coupling portion 32. The breakable tether 212 comprises a coupling segment 31 extending along the coupling portion 32 of the periphery. The coupling segment 31 of the breakable tether 212 couples the coupling portion 32 to the breaking region 213 of the breakable tether 212. The breakable tether 212 extends along the traverse direction 2 traverse to the periphery of the device coupon 201. The crack arrest pattern 222 is formed in the device coupon 201 at a distance 15 from the coupling portion 32 equal to or larger than a length of the coupling portion 32 along the periphery. A length of the crack arrest pattern 222 along the parallel direction 3 parallel to the periphery of the device coupon 201 is equal to or larger than half the length of the coupling portion 32 along the periphery. In this example, a midline along the parallel direction 3 of the breakable tether 212, wherein the midline extends along the traverse direction 2 as depicted in the line A′-A′ on FIG. 2 and wherein the distance 16 is equal to the distance 17, does not coincide with a midline along the parallel direction 3 of the crack arrest pattern 222. A width of the crack arrest pattern 222 along the traverse direction 2 fans out with an increasing distance from the midline of the crack arrest pattern 222. The source wafer 1 further comprises a cavity 300 extending at least partially between the device coupon 201 and the substrate and at least partially around the device coupon 201. The cavity 300 is bridged by the breakable tether 212, thereby securing the device coupon 201 to the substrate.

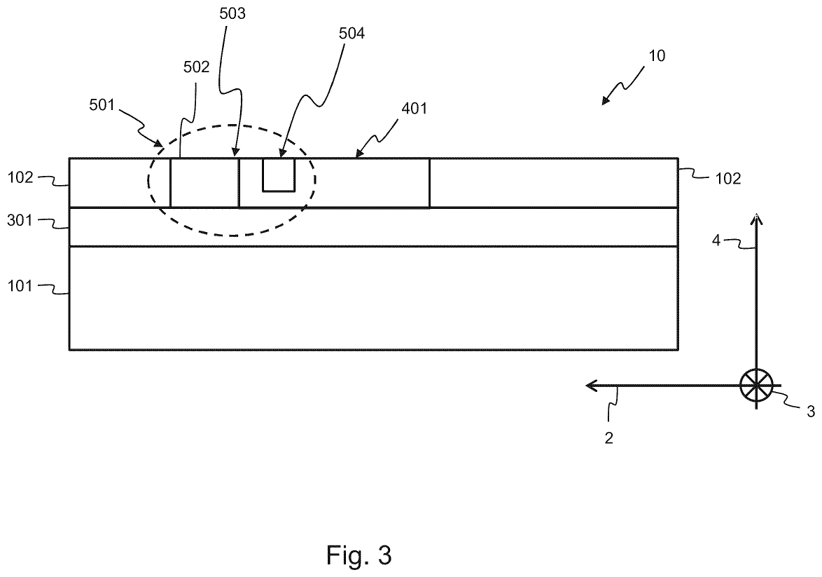

FIG. 3 schematically depicts a side view of an example embodiment of a source wafer 10 to be manufactured into the source wafer for micro-transfer printing according to the present disclosure. This side view is a view of the source wafer 1 of FIG. 2 in cross-section along the line A′-A′ shown on FIG. 2. Components having identical reference numbers to components in FIG. 1 or FIG. 2 perform the same function. The source wafer 10 comprises a substrate 101. The source wafer 10 further comprises a sacrificial layer 301 provided on top of the substrate 101. The source wafer 10 further comprises a semiconductor film 102 on top of the sacrificial layer 301. A designed device coupon 401 is defined on the semiconductor film 102. A designed micro-transfer printing pair 501 is defined at the periphery of the designed device coupon 401. The designed micro-transfer printing pair 501 comprises a designed breakable tether 502 comprising a designed breaking region 503 and a designed crack arrest pattern 504 defined in the designed device coupon 401. The sacrificial layer 301 is to be etched away at least partially between the designed device coupon 401 and the substrate 101, thereby forming a device coupon suspended above the substrate 101 and a cavity 300 extending at least partially between the device coupon and the substrate 101 and at least partially around the device coupon. The sacrificial layer 301 is to be etched away at least partially between the designed breakable tether 502 and the substrate 101, thereby forming a breakable tether securing the device coupon to the substrate 101 and bridging the cavity 300 by the breakable tether 212. The designed crack arrest pattern 504 is to be etched away at least partially through the device coupon, thereby forming a crack arrest pattern according to the present disclosure.

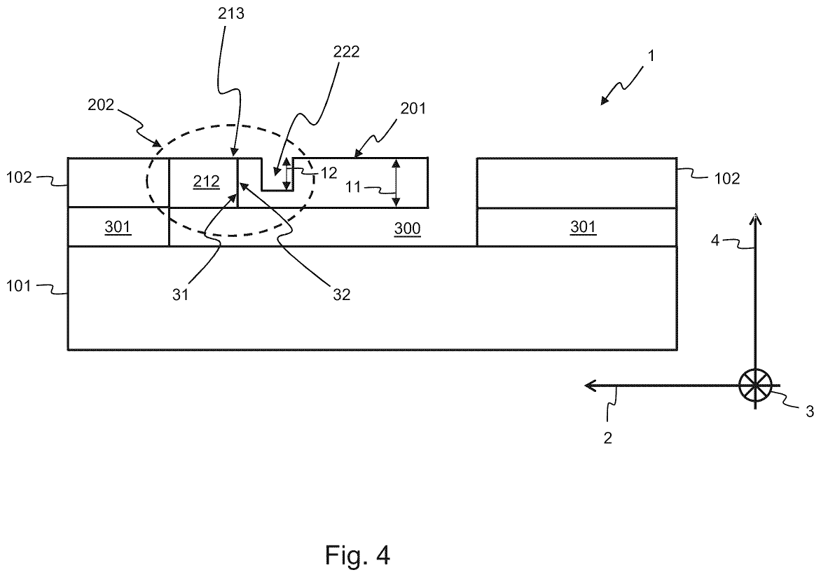

FIG. 4 schematically depicts a side view of an example embodiment of a source wafer 1 for micro-transfer printing according to the present disclosure, wherein the source wafer 1 is manufactured from the source wafer 10 of FIG. 3. This side view is a view of the source wafer 1 of FIG. 2 in cross-section along the line A′-A′ shown on FIG. 2. Components having identical reference numbers to components in FIG. 1 or FIG. 2 or FIG. 3 perform the same function. The source wafer 1 comprises a substrate 101. The source wafer 1 further comprises a sacrificial layer 301 provided on top of the substrate 101. The source wafer 1 further comprises a semiconductor film 102 on top of the sacrificial layer 301. A device coupon 201 is defined on the semiconductor film 102. A micro-transfer printing pair 202 is defined at the periphery of the device coupon 201. The micro-transfer printing pair 202 comprises a breakable tether 212 comprising a breaking region 213. The micro-transfer printing pair 202 further comprises a crack arrest pattern 222 defined in the device coupon 201, wherein the crack arrest pattern 222 extends at least partially through the device coupon 201 along the third direction 4 traverse to the traverse direction 2 and to the parallel direction 3. The depth 12 of the crack arrest pattern 222 along the third direction 4 is equal to or larger than 50% of the depth 11 of the device coupon along the third direction 4 traverse to the traverse direction 2 and to the parallel direction 3. Optionally, the breakable tether 212 comprises an opening or trench extending along the traverse direction 2. The breaking region 213 of the breakable tether 212 is thinner than adjacent regions of the breakable tether 212 along the third direction 4 and/or the breaking region 213 of the breakable tether 212 is narrower than adjacent regions of the breakable tether 212 along the parallel direction 3. The periphery of the device coupon 201 comprises a coupling portion 32. The breakable tether 212 comprises a coupling segment 31 extending along the coupling portion 32 of the periphery. The coupling segment 31 of the breakable tether 212 couples the coupling portion 32 to the breaking region 213 of the breakable tether 212. The breakable tether 212 extends along the traverse direction 2 traverse to the periphery of the device coupon 201. The source wafer 1 further comprises a cavity 300 extending at least partially between the device coupon 201 and the substrate and at least partially around the device coupon 201. The cavity 300 is bridged by the breakable tether 212, thereby securing the device coupon 201 to the substrate.

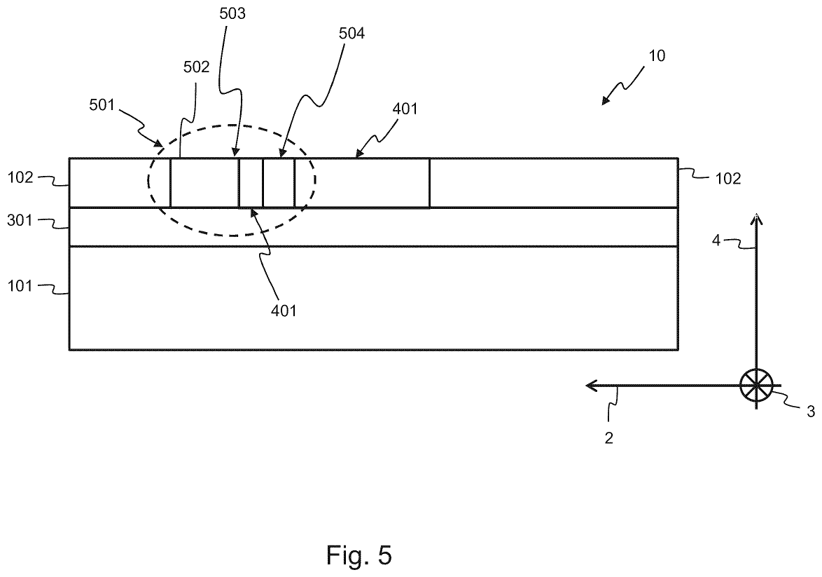

FIG. 5 schematically depicts a side view of an example embodiment of a source wafer 10 to be manufactured into the source wafer for micro-transfer printing according to the present disclosure. This side view is a view of the source wafer 1 of FIG. 2 in cross-section along the line A′-A′ shown on FIG. 2. Components having identical reference numbers to components in FIG. 1 or FIG. 2 perform the same function. The source wafer 10 comprises a substrate 101. The source wafer 10 further comprises a sacrificial layer 301 provided on top of the substrate 101. The source wafer 10 further comprises a semiconductor film 102 on top of the sacrificial layer 301. A designed device coupon 401 is defined on the semiconductor film 102. A designed micro-transfer printing pair 501 is defined at the periphery of the designed device coupon 401. The designed micro-transfer printing pair 501 comprises a designed breakable tether 502 comprising a designed breaking region 503 and a designed crack arrest pattern 504 defined in the designed device coupon 401. The sacrificial layer 301 is to be etched away at least partially between the designed device coupon 401 and the substrate 101, thereby forming a device coupon suspended above the substrate 101 and a cavity 300 extending at least partially between the device coupon and the substrate 101 and at least partially around the device coupon. The sacrificial layer 301 is to be etched away at least partially between the designed breakable tether 502 and the substrate 101, thereby forming a breakable tether securing the device coupon to the substrate 101 and bridging the cavity 300 by the breakable tether 212. The designed crack arrest pattern 504 is to be etched away through the device coupon, thereby forming a crack arrest pattern according to the present disclosure.

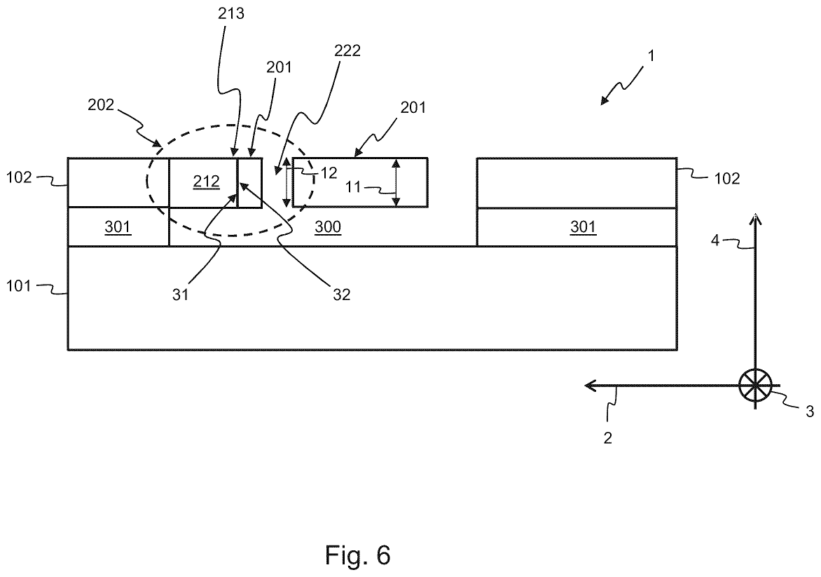

FIG. 6 schematically depicts a side view of an example embodiment of a source wafer 1 for micro-transfer printing according to the present disclosure, wherein the source wafer 1 is manufactured from the source wafer 10 of FIG. 5. This side view is a view of the source wafer 1 of FIG. 2 in cross-section along the line A′-A′ shown on FIG. 2. Components having identical reference numbers to components in FIG. 1 or FIG. 2 or FIG. 5 perform the same function. The source wafer 1 comprises a substrate 101. The source wafer 1 further comprises a sacrificial layer 301 provided on top of the substrate 101. The source wafer 1 further comprises a semiconductor film 102 on top of the sacrificial layer 301. A device coupon 201 is defined on the semiconductor film 102. A micro-transfer printing pair 202 is defined at the periphery of the device coupon 201. The micro-transfer printing pair 202 comprises a breakable tether 212 comprising a breaking region 213. The micro-transfer printing pair 202 further comprises a crack arrest pattern 222 defined in the device coupon 201, wherein the crack arrest pattern 222 extends through the device coupon 201 along the third direction 4 traverse to the traverse direction 2 and to the parallel direction 3. The depth 12 of the crack arrest pattern 222 along the third direction 4 is equal to the depth 11 of the device coupon along the third direction 4 traverse to the traverse direction 2 and to the parallel direction 3. Optionally, the breakable tether 212 comprises an opening or trench extending along the traverse direction 2. The breaking region 213 of the breakable tether 212 is thinner than adjacent regions of the breakable tether 212 along the third direction 4 and/or the breaking region 213 of the breakable tether 212 is narrower than adjacent regions of the breakable tether 212 along the parallel direction 3. The periphery of the device coupon 201 comprises a coupling portion 32. The breakable tether 212 comprises a coupling segment 31 extending along the coupling portion 32 of the periphery. The coupling segment 31 of the breakable tether 212 couples the coupling portion 32 to the breaking region 213 of the breakable tether 212. The breakable tether 212 extends along the traverse direction 2 traverse to the periphery of the device coupon 201. The source wafer 1 further comprises a cavity 300 extending at least partially between the device coupon 201 and the substrate and at least partially around the device coupon 201. The cavity 300 is bridged by the breakable tether 212, thereby securing the device coupon 201 to the substrate.

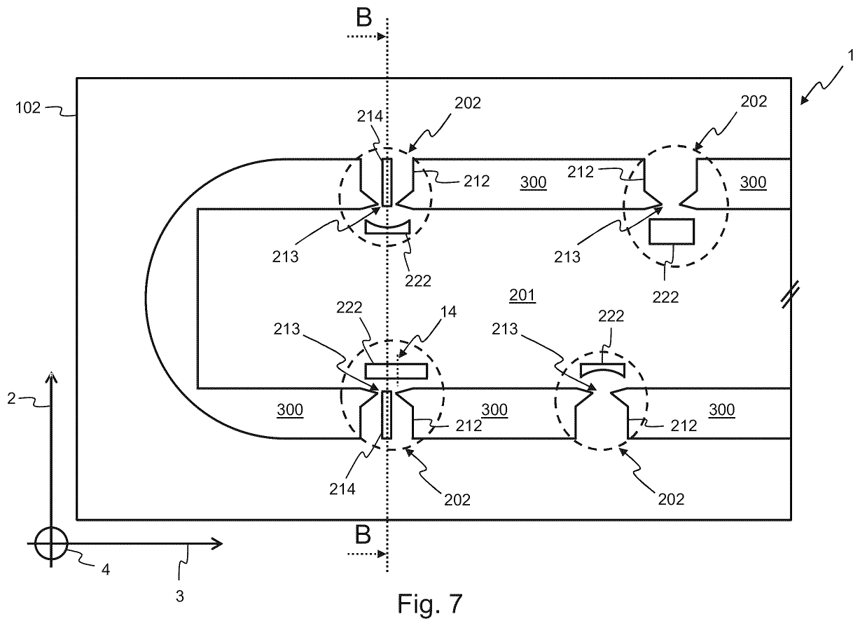

FIG. 7 schematically depicts a top view of an example embodiment of a source wafer 1 for micro-transfer printing according to the present disclosure. The source wafer 1 comprises a substrate and a semiconductor film 102 on top of the substrate. The semiconductor film 102 comprises a device coupon 201 and several micro-transfer printing pairs 202. The micro-transfer printing pairs 202 are distributed along the periphery of the device coupon 201. For example, the micro-transfer printing pairs 202 are evenly distributed, for example periodically, along the periphery of the device coupon 201. According to an alternative embodiment, the micro-transfer printing pairs 202 are not evenly distributed along the periphery of the device coupon 201 and may for example be concentrated closer to or further away from the device features being manufactured onto the device coupon 201. For example, two adjacent breakable tethers are separated by hundreds of μm. Each micro-transfer printing pair 202 is formed at the periphery of the device coupon 201. Each micro-transfer printing pair 202 comprises a breakable tether 212 securing the device coupon 201 to the substrate. Each breakable tether 212 comprises a breaking region 213. Each micro-transfer printing pair 202 further comprises at least one crack arrest pattern 222 formed in the device coupon 201 and extending at least partially through the device coupon along the third direction 4 traverse to the traverse direction 2 and to the parallel direction 3. Optionally, one or more breakable tethers 212 comprise one or more openings 214 or trenches 214 extending along the traverse direction 2. For each micro-transfer printing pair 202, the breaking region 213 of a breakable tether 212 is thinner than adjacent regions of the breakable tether 212 along the third direction 4 and/or the breaking region 213 of the breakable tether 212 is narrower than adjacent regions of the breakable tether 212 along the parallel direction 3. A midline along the parallel direction 3 of a breakable tether 212, wherein the midline extends along the traverse direction 2 as depicted in the line B-B on FIG. 7, may coincide with a midline along the parallel direction 3 of the crack arrest pattern 222, for example as shown on FIG. 7 for the top left micro-transfer printing pair 202. As shown on FIG. 7 for the bottom left micro-transfer printing pair 202, a midline along the parallel direction 3 of a breakable tether 212, wherein the midline extends along the traverse direction 2 as depicted in the line B-B on FIG. 7, may not coincide with a midline 14 along the parallel direction 3 of the crack arrest pattern 222. A width of the crack arrest pattern 222 along the traverse direction 2 may fan out with an increasing distance from the midline of the crack arrest pattern 222, for example for the top left and the bottom right crack arrest patterns 222 on FIG. 7. As shown on FIG. 7 for the top right and bottom left crack arrest patterns 222, a width of the crack arrest pattern 222 along the traverse direction 2 may not fan out with an increasing distance from the midline of the crack arrest pattern 222 The source wafer 1 further comprises a cavity 300 extending at least partially between the device coupon 201 and the substrate and at least partially around the device coupon 201. The cavity 300 is bridged by the breakable tethers 212, thereby securing the device coupon 201 to the substrate.

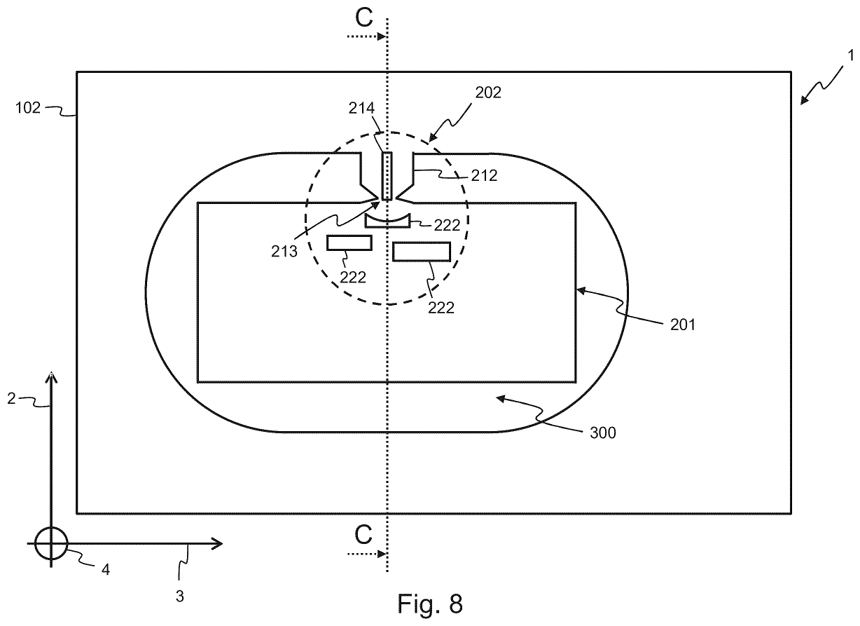

FIG. 8 schematically depicts a top view of an example embodiment of a source wafer 1 for micro-transfer printing according to the present disclosure. The source wafer 1 comprises a substrate and a semiconductor film 102 on top of the substrate. The semiconductor film 102 comprises a device coupon 201 and a micro-transfer printing pair 202. The micro-transfer printing pair 202 is formed at the periphery of the device coupon 201. The micro-transfer printing pair 202 comprises a breakable tether 212 securing the device coupon 201 to the substrate. The breakable tether 212 comprises a breaking region 213. The micro-transfer printing pair 202 further comprises three crack arrest patterns 222 formed in the device coupon 201 and extending at least partially through the device coupon along the third direction 4 traverse to the traverse direction 2 and to the parallel direction 3. Optionally, the breakable tether 212 comprises an opening 214 or trench 214 extending along the traverse direction 2. The breaking region 213 of the breakable tether 212 is thinner than adjacent regions of the breakable tether 212 along the third direction 4 and/or the breaking region 213 of the breakable tether 212 is narrower than adjacent regions of the breakable tether 212 along the parallel direction 3. A midline along the parallel direction 3 of the breakable tether 212, wherein the midline extends along the traverse direction 2 as depicted in the line C-C on FIG. 8, may or may not coincide with a midline along the parallel direction 3 of one or more crack arrest patterns 222. A width of one or more crack arrest patterns 222 along the traverse direction 2 may or may not fan out with an increasing distance from the midline of the crack arrest pattern 222. The source wafer 1 further comprises a cavity 300 extending at least partially between the device coupon 201 and the substrate and at least partially around the device coupon 201. The cavity 300 is bridged by the breakable tether 212, thereby securing the device coupon 201 to the substrate.

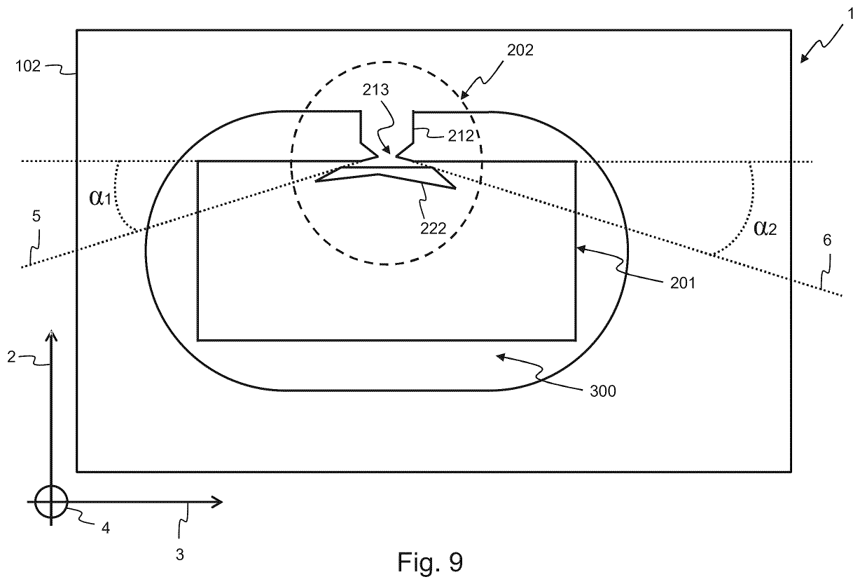

FIG. 9 schematically depicts a top view of an example embodiment of a source wafer 1 for micro-transfer printing according to the present disclosure. The source wafer 1 comprises a substrate and a semiconductor film 102 on top of the substrate. The semiconductor film 102 comprises a device coupon 201 and a micro-transfer printing pair 202. The micro-transfer printing pair 202 is formed at the periphery of the device coupon 201. The micro-transfer printing pair 202 comprises a breakable tether 212 securing the device coupon 201 to the substrate. The breakable tether 212 comprises a breaking region 213. The micro-transfer printing pair 202 further comprises at least one crack arrest pattern 222 formed in the device coupon 201 and extending at least partially through the device coupon along the third direction 4 traverse to the traverse direction 2 and to the parallel direction 3. Optionally, the breakable tether 212 comprises an opening or trench extending along the traverse direction 2. The breaking region 213 of the breakable tether 212 is thinner than adjacent regions of the breakable tether 212 along the third direction 4 and/or the breaking region 213 of the breakable tether 212 is narrower than adjacent regions of the breakable tether 212 along the parallel direction 3. A midline along the parallel direction 3 of the breakable tether 212, wherein the midline extends along the traverse direction 2 may or may not coincide with a midline along the parallel direction 3 of the crack arrest pattern 222. A width of the crack arrest pattern 222 along the traverse direction 2 may or may not fan out with an increasing distance from the midline of the crack arrest pattern 222. The source wafer 1 further comprises a cavity 300 extending at least partially between the device coupon 201 and the substrate and at least partially around the device coupon 201. The cavity 300 is bridged by the breakable tether 212, thereby securing the device coupon 201 to the substrate. The crack arrest pattern 222 is formed in the device coupon 201 between two lines 5; 6, wherein the lines 5; 6 originate form the extremities of the coupling segment 31. The line 5 extends away from the coupling portion 32 under an angle α₁ comprised between 0.3° and 89° from the periphery of the device coupon 201. The line 6 extends away from the coupling portion 32 under an angle α₂ comprised between 0.3° and 89° from the periphery of the device coupon 201. The two angles α₁ and α₂ may be identical or may be different from one another.

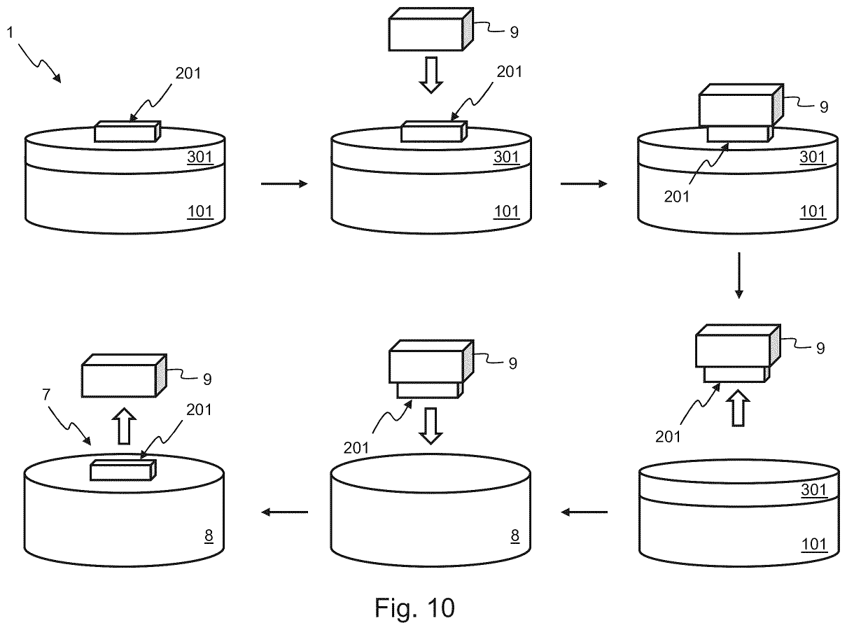

FIG. 10 schematically depicts a method of manufacturing a semiconductor device 7 heterogeneously integrated onto a target substrate 8 via micro-transfer printing using the source wafer 1 of any of the previous figures FIG. 1 or FIG. 2 or FIG. 4 or FIG. 6 or FIG. 7 or FIG. 8 or FIG. 9, and according to the present disclosure. The method comprises providing a source wafer 1 according to the present disclosure, wherein the source wafer 1 comprises a substrate 101, a sacrificial layer 301 and a device coupon 201. In the subsequent method step, a stamp 9 is provided and is lowered onto the device coupon 201 up until the stamp 9 comes in contact with the uppermost surface of the device coupon 201. In the subsequent method step, the device coupon 201 is adhered onto a stamp 9, for example by applying mechanical pressure onto the stamp 9. In the subsequent method step, the device coupon 201 adhered onto the stamp 9 is lifted away from the substrate 101, thereby breaking one or more breakable tethers at the breakable regions. In the subsequent method step, a target substrate 8 is provided and the device coupon 201 adhered onto the stamp 9 is lowered onto the target substrate 8. In the subsequent method step, the device coupon 201 adhered onto the stamp 9 is pressed onto the target substrate 8, thereby printing the device coupon 201 onto the target substrate 8 and forming the semiconductor device 7.

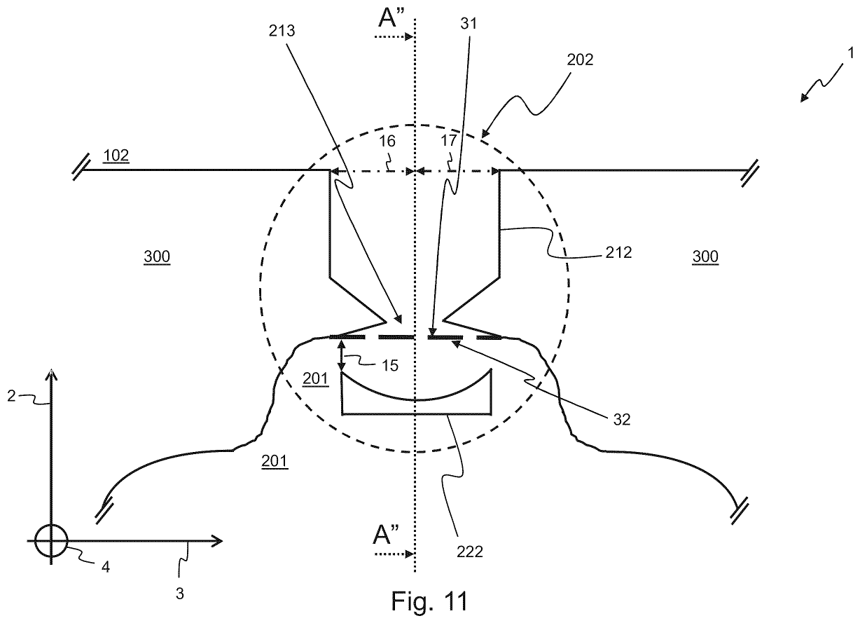

FIG. 11 schematically depicts a top view of a zoom on an example embodiment of a micro-transfer printing pair 202 of a source wafer 1 for micro-transfer printing according to the present disclosure. Components having identical reference numbers to components in FIG. 1 perform the same function. The source wafer 1 comprises a substrate and a semiconductor film 102 on top of the substrate. The semiconductor film 102 comprises a device coupon 201 and a micro-transfer printing pair 202. The micro-transfer printing pair 202 is formed at the periphery of the device coupon 201. The periphery of the device coupon 201 can have any shape, size and form. The micro-transfer printing pair 202 comprises a breakable tether 212 securing the device coupon 201 to the substrate. The breakable tether 212 comprises a breaking region 213. The micro-transfer printing pair 202 further comprises at least one crack arrest pattern 222 formed in the device coupon 201 and extending at least partially through the device coupon along the third direction 4 traverse to the traverse direction 2 and to the parallel direction 3. Optionally, the breakable tether 212 comprises an opening or trench extending along the traverse direction 2. The breaking region 213 of the breakable tether 212 is thinner than adjacent regions of the breakable tether 212 along the third direction 4 and/or the breaking region 213 of the breakable tether 212 is narrower than adjacent regions of the breakable tether 212 along the parallel direction 3. The periphery of the device coupon 201 comprises a coupling portion 32. The breakable tether 212 comprises a coupling segment 31 extending along the coupling portion 32 of the periphery. The coupling segment 31 of the breakable tether 212 couples the coupling portion 32 to the breaking region 213 of the breakable tether 212. The breakable tether 212 extends along the traverse direction 2 traverse to the periphery of the device coupon 201. The crack arrest pattern 222 is formed in the device coupon 201 at a distance 15 from the coupling portion 32 equal to or larger than a length of the coupling portion 32 along the periphery. A length of the crack arrest pattern 222 along the parallel direction 3 parallel to the periphery of the device coupon 201 is equal to or larger than half the length of the coupling portion 32 along the periphery. In this example, a midline along the parallel direction 3 of the breakable tether 212, wherein the midline extends along the traverse direction 2 as depicted in the line A″-A″ on FIG. 11 and wherein the distance 16 is equal to the distance 17, does not coincide with a midline along the parallel direction 3 of the crack arrest pattern 222. A width of the crack arrest pattern 222 along the traverse direction 2 fans out with an increasing distance from the midline of the crack arrest pattern 222. The source wafer 1 further comprises a cavity 300 extending at least partially between the device coupon 201 and the substrate and at least partially around the device coupon 201. The cavity 300 is bridged by the breakable tether 212, thereby securing the device coupon 201 to the substrate.

Although the present invention has been illustrated by reference to specific embodiments, it will be apparent to those skilled in the art that the invention is not limited to the details of the foregoing illustrative embodiments, and that the present invention may be embodied with various changes and modifications without departing from the scope thereof. The present embodiments are therefore to be considered in all respects as illustrative and not restrictive, the scope of the invention being indicated by the appended claims rather than by the foregoing description, and all changes which come within the scope of the claims are therefore intended to be embraced therein.

It will furthermore be understood by the reader of this patent application that the words “comprising” or “comprise” do not exclude other elements or steps, that the words “a” or “an” do not exclude a plurality, and that a single element, such as a computer system, a processor, or another integrated unit may fulfil the functions of several means recited in the claims. Any reference signs in the claims shall not be construed as limiting the respective claims concerned. The terms “first”, “second”, third”, “a”, “b”, “c”, and the like, when used in the description or in the claims are introduced to distinguish between similar elements or steps and are not necessarily describing a sequential or chronological order. Similarly, the terms “top”, “bottom”, “over”, “under”, and the like are introduced for descriptive purposes and not necessarily to denote relative positions. It is to be understood that the terms so used are interchangeable under appropriate circumstances and embodiments of the invention are capable of operating according to the present invention in other sequences, or in orientations different from the one(s) described or illustrated above.

1.-15. (canceled)

16. A source wafer for micro-transfer printing, wherein said source wafer comprises:
a substrate; and
on top of said substrate, a semiconductor film comprising:
a device coupon comprising a periphery corresponding to a boundary of said device coupon,
wherein said periphery comprises a coupling portion; and
a micro-transfer printing pair formed at said periphery of said device coupon,
wherein said micro-transfer printing pair comprises:
a breakable tether securing said device coupon to said substrate,
wherein said breakable tether comprises a breaking region narrower than adjacent regions of said breakable tether along a parallel direction parallel to said periphery of said device coupon, said breaking region thereby having a lower shear strength than said adjacent regions; and
wherein said breakable tether comprises a coupling segment coupling said coupling portion to said breaking region; and
at least one crack arrest pattern formed in said device coupon and extending at least partially through said device coupon;
wherein said coupling portion extends between said crack arrest pattern and said breaking region.

17. The source wafer according to claim 16, wherein said crack arrest pattern extends through said device coupon.

18. The source wafer according to claim 16, wherein said coupling segment extends along said coupling portion of said periphery.

19. The source wafer according to claim 18, wherein said breakable tether extends along a traverse direction traverse to said periphery of said device coupon; and
wherein said crack arrest pattern is formed in said device coupon at a distance from said coupling portion equal to or larger than a length of said coupling portion along said periphery.

20. The source wafer according to claim 18, wherein a length of said crack arrest pattern along a parallel direction parallel to said periphery of said device coupon is equal to or larger than half the length of said coupling portion along said periphery.

21. The source wafer according to claim 19, wherein said breaking region is thinner than adjacent regions of said breakable tether along a third direction traverse to said traverse direction and to said parallel direction.

22. The source wafer according to claim 20, wherein a midline of said breakable tether along said parallel direction coincides with a midline of said crack arrest pattern along said parallel direction.

23. The source wafer according to claim 19, wherein a width of said crack arrest pattern along said traverse direction fans out with an increasing distance from said midline of said crack arrest pattern.

24. The source wafer according to claim 16, wherein said source wafer further comprises a cavity extending at least partially between said device coupon and said substrate and at least partially around said device coupon;
wherein said cavity is bridged by said breakable tether, thereby securing said device coupon to said substrate.

25. The source wafer according to claim 16, wherein said micro-transfer printing pair comprises a plurality of crack arrest patterns.

26. The source wafer according to claim 18, wherein said crack arrest patterns are formed in said device coupon between two lines originating from extremities of said coupling segment and each extending away from said coupling portion under an angle comprised between 0.3° and 89° from said periphery of said device coupon.

27. The source wafer according to claim 16, wherein said semiconductor film comprises a plurality of micro-transfer printing pairs formed along said periphery of said device coupon.

28. A method for forming a source wafer for micro-transfer printing, said method comprising the steps of:
providing a substrate;
on top of said substrate, providing a sacrificial layer;
on top of said sacrificial layer, providing a semiconductor film;
defining a designed device coupon on said semiconductor film;
defining a designed micro-transfer printing pair at a periphery of said designed device coupon,
wherein said designed micro-transfer printing pair comprises:
a designed breakable tether comprising a designed breaking region; and
a designed crack arrest pattern defined in said designed device coupon;
etching:
said sacrificial layer away at least partially between said designed device coupon and said substrate, thereby forming a device coupon suspended above said substrate and a cavity extending at least partially between said device coupon and said substrate and at least partially around said device coupon; said device coupon comprising a periphery corresponding to a boundary of said device coupon,
wherein said periphery comprises a coupling portion;
said sacrificial layer away at least partially between said designed breakable tether and said substrate, thereby forming a breakable tether comprising a breakable region narrower than adjacent regions of said breakable tether along a parallel direction parallel to said periphery of said device coupon, said breaking region thereby having a lower shear strength than said adjacent regions;
wherein said breakable tether comprises a coupling segment coupling said coupling portion to said breaking region along said periphery; and
wherein said breakable tether secures said device coupon to said substrate and bridges said cavity by said breakable tether; and
said designed crack arrest pattern at least partially through said device coupon, thereby forming a crack arrest pattern with said coupling portion extending between said crack arrest pattern and said breaking region.

29. A method of manufacturing a semiconductor device heterogeneously integrated onto a target substrate via micro-transfer printing using the source wafer of claim 16, wherein said method comprises the steps of:
adhering said device coupon onto a stamp;
lifting said device coupon adhered onto said stamp away from said substrate, thereby breaking one or more of said breakable tethers at said breakable regions; and
pressing said device coupon adhered onto said stamp onto said target substrate, thereby printing said device coupon onto said target substrate.

30. A semiconductor device manufactured using the method of claim 29.
